(19) United States
(12) Patent Application Publication
(10) Pub. No.: US 2015/0194295 A1
(43) Pub. Date: Jul. 9, 2015

(54) ASSEMBLY FOR USE IN A VACUUM TREATMENT PROCESS

(71) Applicant: UAB Nova Fabrica, Ignalina (LT)

(72) Inventor: Martynas Audronis, Ignalina (LT)

(73) Assignee: UAB Nova Fabrica, Ignalina (LT)

(21) Appl. No.: 14/412,883

(22) PCT Filed: Feb. 4, 2013
(86) PCT No.: PCT/IB2013/050941

§ 371 Date: Jan. 5, 2015

(30) Foreign Application Priority Data
Jul. 13, 2012 (GB) 1212540.7

(51) Int. Cl. H01J 49/00; H01J 37/34; C23C 14/54; C23C 14/35; C23C 14/52

(52) U.S. Cl. CPC H01J 49/0013; C23C 14/35; C23C 14/52; C23C 14/54; H01J 37/3476; H01J 2237/2002; H01J 2237/332

(57) ABSTRACT

An assembly for use in a vacuum treatment process, the assembly including a process changer 1. Gas analysis apparatus to sample and analyse the gas composition within the chamber 1 is provided. The gas analysis apparatus includes a measuring apparatus 14 based either on a miniature mass spectrometer or on a miniature plasma source, which is located within an elongate housing 18. Part of the housing 18 is located within the process chamber 1 such that the gas is analysed within the chamber 1. The process can be controlled in response to the gas analysis

This invention relates to an assembly for use in a vacuum treatment process, and a method of carrying out a vacuum treatment process, including physical or chemical coating processes or plasma etching processes.

Vacuum fabrication and treatment methods, such as Physical Vapour Deposition (PVD), Chemical Vapour Deposition (CVD) and low temperature plasma processing, are used in systems for surface engineering purposes in production and research. Vacuum treatment processes can be either inherently unstable (e.g. reactive magnetron sputtering processes can exhibit fast transition between sputter target states, hysteresis behaviour and arcing [Surface & Coatings Technology 204 (2010) 2159-2164]) or prone to drifts in processing parameters (due for example to material consumption or to local environmental changes, such as chamber temperature and outgassing). As a result of such instabilities operation of systems can be difficult and there may be issues in terms of process reproducibility and product quality. Open loop or closed loop (or a combination of both) process control systems are therefore often employed in an attempt to stabilise certain vacuum processes. Such control systems often employ sensors that are engineered to monitor processes and supply the control system with signals representing the state of these processes. Based on these signals the control system can adjust parameters of processes monitored via actuators (such as gas flow controllers or electrical power supplies) in order to maintain certain process characteristics at a desired set-point. Fast sensor response times, data processing and actuation (e.g. of the order of a few milliseconds) may be needed in order to control fast changing processes.

A variety of sensor technologies exist that can be used to analyse gas or a mixture of gasses for monitoring and controlling vacuum treatment processes. These sensor technologies can be grouped roughly by sensor head design into two major groups: a) sensors that require means for conditioning the monitored environment or the sensor head itself (e.g. alternating or direct current voltage for ionisation and/or excitation of gas, electrolyte heating) in order to produce a usable feedback signal and b) sensor heads that allow monitoring and enable producing a feedback signal with no such conditioning. For the convenience, in this document we shall be referring to the first of the two groups as “internally conditioned sensors”.

Internally conditioned sensors often incorporate and are based on means such as mass spectrometers, gas ionisation sources and solid electrolytes.

Sensors that condition and analyse gas represent by themselves a gas analysis apparatus. A gas analysis apparatus in such a case normally comprises a receiving part, which contains or is in contact with the gas being analysed and a measuring part. The latter carries out conditioning of the gas (contained by or adjacent to the receiving part) by, for example, ionising or exciting it. The measuring part measures properties of the contained gas, such as the presence and amount of certain charged or excited species, and produces optical and/or electrical signals that represent measurement results.

If the gas analysis apparatus is comprised of a plasma source coupled with Optical Emission Spectrometry means, then components of the measuring part, such as the means responsible for ignition and driving of the plasma in or adjacent to the receiving part maybe located both on the vacuum side and on the atmospheric side; other components of the measuring part, such as an optical assembly responsible for transmitting and processing light tends to be located on the atmospheric side, but some of it may be on the vacuum side either.

Further paragraphs provide examples of current art involving different sensors/gas analysis apparatuses.

U.S. Pat. No. 4,428,811 discloses a method and apparatus for rapid rate magnetron sputter deposition of metallic compounds. In the process a vacuum chamber is filled with an inert gas that is ionised and bombards the metal target within the chamber to initiate the sputtering process. A second reactive gas is fed into the chamber at a measured rate to combine with atomised metal from the target and form a coating on the substrate. Control system employs a mass spectrometer-based gas analysis apparatus that provides a control signal used to regulate admission of the reactive gas at the proper rate for the most effective processing conditions. A typical mass spectrometer setup and its functionality used in such case is disclosed in U.S. Pat. No. 4,362,936 and references therein.

Some disadvantages of using such mass spectrometers for process control solutions are: i) necessity to operate a mass spectrometer at a much higher vacuum level than that of a typical vacuum or plasma process, ii) size of the mass spectrometer assembly iii) severe constraints on possible locations where a sensor can be attached to the system, which does not allow for the most optimal performance iii) demanding maintenance and iv) prohibitively high cost for use in multiple sensor head setups.

Another example of an internally conditioned sensor technology that can be used for controlling vacuum processes is a plasma source-based sensor head used in conjunction with optical emission spectroscopy (OES) and optical monitoring of exited process gas or a mixture of process gases. The gas is excited by external means, i.e. independently from essential process components, such as deposition source, by, for example, an electron beam (e.g. U.S. Pat. No. 4,692,630) or a DC voltage (e.g. UK Patent Application GB2441582A). Optical monitoring is then carried out by using one or more photomultiplier tubes or other detectors to detect wavelengths of photons characteristic of the decay of the outer electrons of one or more species of gas molecules. Thin film interference filters, a monochromator or a spectrometer (e.g. a CCD spectrometer) can be used to pass a specific characteristic wavelength of the desired species. The disadvantage of such sensors is their size and geometry, which complicate and limit options for optimal sensor integration in the processing system. UK Patent Application GB2441582A mentions “local” positioning of such sensors, but does not explain what that means or how it would be possible using the disclosed technology neither in the patent application text nor in the figures.

Another example of the internally conditioned sensor technology used in vacuum processing systems is known as air-to-fuel sensor (or A-probe) [U.S. Pat. No. 5,696,313] as it was originally developed for automotive exhausts. In A-probe case oxygen concentration in a gas mixture can be measured with the aid of a solid body electrolyte (e.g. yttria stabilized zirconium dioxide) and platinum electrodes. Air is most often utilised as the reference gas. The upper surface of one side of the solid electrolyte is placed in contact with the gas mixture to be measured and the upper surface of the other side of the solid electrolyte is placed in contact with air. The differential of the oxygen partial pressures then creates an electrical signal whose magnitude is dependent upon the concentration of oxygen in the measurement gas. The electrical signal is then conditioned by electrical circuits and used by a control system to adjust processing parameters, such as reactive gas flow rate [Thin Solid Films 502 (2006) 44-49]. Some disadvantages of lambda sensors are i) the need for air reference, which limits severely placement options of lambda sensors in the processing system as well as complicates system design ii) the need for heating, which, adds expense and complicates the system design iii) relatively slow response time [Thin Solid Films 491 (2005) 1-17] and iv) ability to monitor only oxygen.

In cases when plasma generating components (e.g. magnetron sputter or plasma/ion sources) are used for processing in vacuum systems, direct optical monitoring of the plasma generated by these devices is possible. The technology is often termed Plasma Emission Monitoring (PEM) [Surface & Coatings Technology 33 (1987) 405-423]. Optical components (hardware) in PEM setups can be essentially the same as in monitoring gas exited by external means, as discussed above. PEM technology offers high flexibility in positioning of sensor heads in the system, due to availability of well developed optical components, as well as fast response time [Surface & Coatings Technology 204 (2010) 2159-2164]. However, the control signals provided by PEM can often be unstable due, for example, to plasma drift or to plasma shifts caused by interaction with moving substrates.

Vacuum processing of large (e.g. 1 to 3 metre wide) substrates presents further challenges as many current applications require that the treatment (e.g. coating or etching) result is highly homogenous. For example, in large area (e.g. up to 3 metre wide) optical coating production, thin film physical thickness uniformity is often required to be below 2% across the width of the substrate. Design features of a process chamber and hardware components, such as anodes or gas inlet bars [UK Patent Application GB2277327], can affect favourably treatment uniformity. However, in addition to optimised hardware design process control systems are often used to improve significantly processing uniformity. Improvement is often achieved by monitoring and controlling process conditions and parameters in several areas within the process space. Such processing is often termed a multiple zone processing and requires multiple sensors and/or actuators as well a process control system with multiple channels [Society of Vacuum Coaters 4ih Annual Technical Conference Proceedings 2004, pp. 44-48].

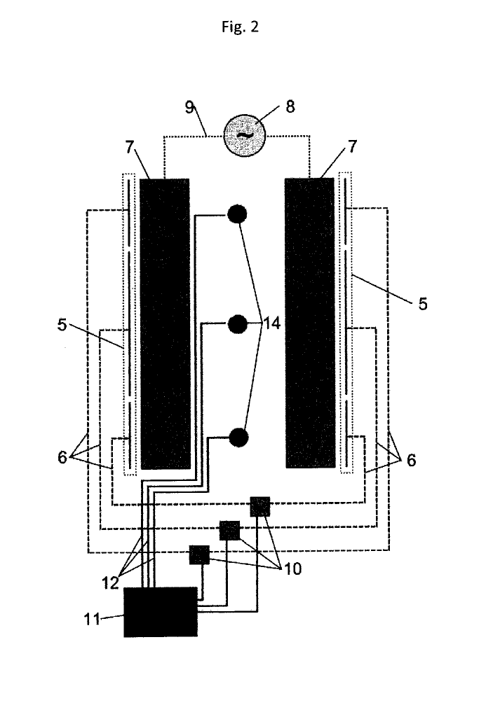

PEM sensor technology provides high degree of flexibility for placing the sensor head in the system and is well suited in the case of multiple sensor installations for multi-zone process control, but suffers from sensor signal stability problems. On the other hand, internally conditioned sensors, such as a mass spectrometer-based sensor or a plasma source-based sensor, can provide good feedback signal stability, but, because of their size and geometry, cannot be integrated easily in vacuum processing systems for most optimal performance. They are usually mounted on or outside the process chamber periphery, for example attached to a pumping line (see FIG. 2 in US 2006/0290925 A1), which limits their efficiency, performance and applicability. It is clear that currently used sensor technologies have numerous drawbacks. More flexible, smaller, simpler to implement, cheaper, suitable for multi-zone control and more sensitive (to changes in a process environment) sensor solutions for vacuum processing are needed.

Miniaturisation of devices is one recent trend in many areas of technology. As it concerns gas ionisation and analysis, innovative designs of components had been proposed by several research groups, which had led to fabrication of miniature mass spectrometers (e.g. Peng et al Trends in Analytical Chemistry, Vol. 30, No. 10, 2011; Ouyang and Cooks Annu. Rev. Anal. Chem. 2009. 2:187-214; Ouyang et al. Eur. J. Mass Spectrom. 13, 13-18, 2007) and miniature plasma sources (e.g. Yin et al. IEEE TRANSACTIONS ON PLASMA SCIENCE, VOL. 27, NO. 5, October 1999 p. 1516; Hopwood et al. J. Vac. Sci. Technol. B 18 (5), September/October 2000 p. 2446; Browning et al. IEEE TRANSACTIONS ON PLASMA SCIENCE, VOL. 39, NO. 11, November 2011 p. 3187).

According to one aspect of the present invention there is provided an assembly for use in a vacuum treatment process, the assembly includes a process chamber which locates at least one process component in the form of a material evaporation source, a sputtering source or a plasma source; and a receiving location for an object being treated, the assembly also includes gas analysis apparatus for monitoring and/or controlling vacuum treatment processes within the process chamber, the gas analysis apparatus including measuring apparatus for analysing gas based either on a miniature mass spectrometer or a miniature plasma source design, the measuring apparatus including a receiving area for gas being analysed, in which receiving area the gas can be conditioned to permit analysis thereof; and a mounting arrangement for mounting the gas analysis apparatus such that the receiving area is adjacent a process component wholly within the process chamber.

A plurality of measuring apparatus may be provided, each of which is spaced from each other and is located wholly within the process chamber.

A part of the gas analysis apparatus may be located outside of the process chamber.

The measuring apparatus may be based on a miniaturised mass spectrometer comprising: an ionisation source for converting gas into charged particles; at least one mass analyser for sorting the resultant ions by mass; at least one ion detector that provides an amplified signal that sensor electronics use to determine mass and abundance; and control electronics.

The mass spectrometer may include a field bus communication interface.

The mass spectrometer may include a miniaturised pumping set, consisting of a rough vacuum pump and/or a high vacuum pump.

The ionisation source may be a resistively heated filament electron ionization source, a Penning Ion Source, a hollow cathode Penning Ion Source, a Glow Discharge Ion Source, a field emission based (e.g. using carbon nano-tubes) electron ionization source or a laser beam.

The mass analyser may be based on a quadruple ion trap, cylindrical ion trap, linear ion trap, rectilinear ion trap, toroidal ion trap, halo ion trap or double-focusing mass spectrometer design, including hybrid variations of the abovementioned designs.

The ion detector may comprise an electron multiplier or a Microchannel Plate multiplier.

The mass spectrometer may operate in either conventional MS or tandem MS/MS mass spectrometry modes.

The mass spectrometer may be a multiplexed mass spectrometer comprising more than one set of sample inlets, ionisation sources, ion-transfer optics, mass analyzers and ion detectors.

The mass spectrometer may operate in a mass selective monitoring mode where ions of one or more selected mass-to-charge ratios are detected and monitored.

The measuring apparatus may be a miniaturised plasma source, comprising: at least one detector to detect light radiation emitted by the plasma in the plasma source; means for analysing the emission spectrum; and control. The sensor apparatus may include a field bus communication interface.

The plasma source may be an inductively coupled plasma source.

The plasma source may comprise a planar spiral shaped coil. The coil may be fabricated on a printed circuit board. Preferably the coil diameter is between 1 and 30 mm and it is mounted on the atmospheric side of a carrying structure component, a portion of which is transparent to light radiation in ultraviolet, visible and/or infrared parts of spectrum and permeable to magnetic fields and radiofrequency waves. The optically transparent material can be quartz, fused silica, sapphire or other type of glass. Preferably a portion of the optically transparent material has a planar surface.

The plasma source may comprise an electronic circuit with components, such as inductors and capacitors, providing impedance matching of the power source.

The plasma source may be driven by alternating current (AC) voltage. The AC voltage frequency may be between 1 kHz and 500 MHz.

The detector may be a photo-sensor module or a spectrometer module, such as a CCD- or CMOS-based spectrometer.

The means for analysing the emission spectrum may comprise a spectrometer, a monochromator, a band pass filter or any combination of the above. More than one wavelength or a range of wavelengths as emitted by plasma may be monitored.

Another aspect of the invention provides a method of carrying out a vacuum treatment process by means of PVD, CVD or low temperature plasma processing carried out using an assembly according to any of the preceding fourteen paragraphs.

The method may include multiple zone processing using more than one gas analysis apparatus and/or actuator as well as a closed loop process control system with multiple channels.

A closed loop control system may be used to regulate devices to maintain a vacuum treatment process in a desired state, in response to signals generated by the measuring apparatus.

Embodiments of the present invention will now be described by way of example only with reference to the accompanying drawings, in which:

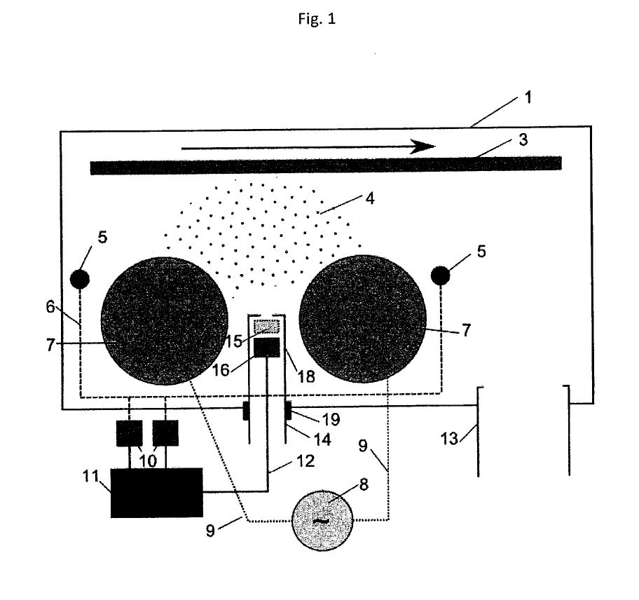

FIG. 1 is a diagrammatic end view of a vacuum coating apparatus according to the invention; and

FIG. 2 is a diagrammatic plan view of a further vacuum coating apparatus according to the invention.

FIG. 1 shows schematically an assembly for use in a vacuum treatment process, in the form of a reactive deposition system which includes a vacuum process chamber 1 filled with inert and reactive gases, such as argon and oxygen. The assembly also includes a moving substrate 3, a dual rotatable magnetron sputtering apparatus 7, an AC power supply 8, a process control system 11, a gas analysis apparatus (sensor) with a measuring apparatus 14 (based either on a miniaturised mass spectrometer or on a miniaturised plasma source and OES) which, due to small size, can be located optimally inside the process chamber near the area of interest, mass flow controllers 10 (one for each type of gas as mentioned above) and gas injection bars 5.

The measuring apparatus 14 is located within an elongate housing 18 part of which is outside the process chamber 1. The housing 18 extends through the wall of the chamber 1 providing the majority thereof within the chamber 1. A vacuum seal 19 is provided around the housing 18. The seal 19 may be of any appropriate type for instance a rubber seal, such as a Quick Falange KF/QF, or a metal seal such as a Conflat CF. Other flange or seal designs could though be used.

The chamber 1 is pumped by vacuum pumps (not shown) through a pumping port 13. AC voltage is applied to the dual magnetron 7 through cabling 9 creating a glow discharge and a flux of sputtered material 4, part of which is deposited onto substrate 3. The deposited material reacts with the reactive gas present in the chamber and forms a compound coating.

The gas housing 18 locates a receiving part 15 and a measuring part 16, which samples the gas composition. A sensor signal representing the gas composition is transmitted through cabling 12 to, and is acquired and processed by, the control system 11. The control system 11 employs an algorithm (e.g. based on control loop feedback mechanisms such as Proportional-Integral-Derivative or Pseudo-Derivative Feedback) to compare current gas composition to a preset set-point value and in the case of divergence adjusts the rate of the reactive gas flow into the chamber by regulating the valve of the mass flow controller 10. The outputs of the mass flow controllers 10 are connected to the gas injection bars 5 by means of tubing 6.

FIG. 2 shows schematically a further example of an assembly for use in a vacuum treatment process, in the form of a reactive deposition system which is similar in most respects to that shown in FIG. 1. Accordingly similar reference numerals have been used for similar components.

In this instance the gas analysis apparatus (sensor) assembly, which again can be a miniaturised mass spectrometer or a miniaturised plasma source, comprises three measuring apparatus 14 which are located within the chamber 1 spaced from each other and spaced between the two magnetrons 7 to provide an accurate gas measurement precisely where this information is required.

Two three-zone gas injection bars 5 for each magnetron are provided, corresponding to some degree in zone relative positions to the three gas measuring apparatus 14, and which can be controlled independently in response to the gas measurements made. A separate controller 10 is provided for each gas injection bar 5, with the controllers 10 being connected to the control system 11.

In assemblies according to the invention the receiving part is always inside the process chamber, i.e. in vacuum, adjacent to the area of interest, which is a process component, such as a magnetron sputter source. The measuring part, depending on the sensor, i.e. gas analysis apparatus design, can be wholly or partly located on the vacuum side, or wholly or partly located on the atmospheric side. For example, if it is a mass spectrometer-based gas analysis apparatus, then most often components of the measuring part, such as an ion source, mass analyser and ion detector are on the vacuum side, while other measuring part components, such as driving electronics, user interface and cables are on the atmospheric side.

There is thus provided a gas analysis apparatus for process monitoring and control that is compact and can be placed with much flexibility inside of a vacuum process chamber.

This invention further provides apparatus for measuring the composition of a gas or a mixture of gasses, providing a feedback signal or signals to a process monitoring and control system and comprising: means for conditioning gaseous environment in or near the monitored area in a process chamber; mass and/or optical emission spectrometry means based on either a miniaturised mass spectrometer or a miniaturised plasma source or both.

There is also provided a method of vacuum surface treating an object comprising locating an object, essential process components and one or more of the gas composition analysing miniaturised sensors in a chamber with a gas in the chamber, and one or more closed loop process control systems that use the sensor signals to monitor and control vacuum surface treatment processes via one or more actuators that are attached to the process chamber or one or more components in the process chamber.

The invention has a number of advantages. The sensor apparatuses provided by the present invention can be located inside a process chamber with a high degree of flexibility thus providing improved monitoring accuracy and more effective control of vacuum treatment processes. They are energy efficient due to miniature design and provide improved feedback signals in terms of stability and reliability. They do so simply and inexpensively, which permits easy implementation on virtually any PVD, CVD or low temperature plasma processing system of virtually any size. They are suitable for multiple zone process monitoring and control.

The processes provided by the present invention are more stable, reproducible, cost-efficient and easier to control due to the use of the sensor apparatuses as provided by this invention.

It is to be realised that a wide range of modifications may be made without departing from the scope of the invention. The assembly can be configured as required for particular vacuum treatment processes.

Whilst endeavouring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

1. An assembly for use in a physical vapour deposition process, the assembly includes a process chamber which locates at least one process component in the form of a material evaporation source, or a sputtering source; and a receiving location for an object being treated, the assembly also includes gas analysis apparatus for monitoring and/or controlling vacuum treatment processes within the process chamber, the gas analysis apparatus including measuring apparatus for analysing gas based either on a miniature mass spectrometer or a miniature plasma source design, the measuring apparatus including a receiving area for gas being analysed, in which receiving area the gas can be conditioned to permit analysis thereof; a mounting arrangement for mounting the gas analysis apparatus such that the receiving area is adjacent a process component wholly within the process chamber, and a closed loop process control system.

2. An assembly according to claim 1, characterised in that a plurality of measuring apparatus are provided, each of which is spaced from each other and is located wholly within the process chamber, wherein a part of the gas analysis apparatus may be located outside the process chamber.

3. (canceled)

4. An assembly according to claim 1, characterised in that the measuring apparatus is based on a miniaturised mass spectrometer comprising: an ionisation source for converting gas into charged particles; at least one mass analyser for sorting the resultant ions by mass; at least one ion detector that provides an amplified signal that sensor electronics use to determine mass and abundance; and control electronics.

5. An assembly according to claim 4, characterised in that the mass spectrometer includes a field bus communication interface, wherein the mass spectrometer may include a miniaturised pumping set consisting of a rough vacuum pump and/or a high vacuum pump, and wherein the ionisation source may be any of a resistively heated filament electron ionization source, a Penning Ion Source, a hollow cathode Penning Ion Source, a Glow Discharge Ion Source, a field emission based (e.g. using carbon nano-tubes) electron ionization source, or a laser beam.

6. (canceled)

7. (canceled)

8. An assembly according to claim 4, characterised in that the mass analyser is based on any of a quadruple ion trap, cylindrical ion trap, linear ion trap, rectilinear ion trap, toroidal ion trap, halo ion trap or double-focusing mass spectrometer design, including hybrid variations of the abovementioned designs.

9. An assembly according to claim 4, characterised in that the ion detector comprises an electron multiplier or a Microchannel Plate multiplier, wherein the mass spectrometer may operate in either conventional MS or tandem MS/MS mass spectrometry modes.

10. (canceled)

11. An assembly according to claim 4, characterised in that the mass spectrometer is a multiplexed mass spectrometer comprising more than one set of sample inlets, ionisation sources, ion-transfer optics, mass analyzers and ion detectors.

12. An assembly according to claim 4, characterised in that the mass spectrometer operates in a mass selective monitoring mode where ions of one or more selected mass-to-charge ratios are detected and monitored.

13. An assembly according to claim 1, characterised in that the measuring apparatus is a miniaturised plasma source comprising: at least one detector to detect light radiation emitted by the plasma in the plasma source; means for analysing the emission spectrum; and control electronics, wherein the sensor apparatus may include a field bus communication interface, and wherein the plasma source may be an inductively coupled plasma source.

14. (canceled)

15. (canceled)

16. An assembly according to claim 13, characterised in that the plasma source comprises a planar spiral shaped coil, wherein the coil may be fabricated on a printed circuit board, and wherein the coil diameter may be between 1 and 30 mm.

17. (canceled)

18. (canceled)

19. An assembly according to claim 16, characterised in that the coil is mounted on the atmospheric side of a carrying structure component, a portion of which is optically transparent to light radiation in ultraviolet, visible and/or infrared parts of spectrum and permeable to magnetic fields and radiofrequency waves, wherein the optically transparent material of the carrying structure component may be any of quartz, fused silica, sapphire or another type of glass.

20. (canceled)

21. An assembly according to claim 19, characterised in that a portion of the optically transparent material of the carrying structure component has a planar surface.

22. An assembly according to claim 9, characterised in that the plasma source comprises an electronic circuit with components, such as inductors and capacitors, providing impedance matching of the power source.

23. An assembly according to claim 13, characterised in that the plasma source is driven by alternating current (AC) voltage, wherein the AC voltage frequency may be between 1 kHz and 500 MHz.

24. (canceled)

25. An assembly according to claim 13, characterised in that the detector is a photo-sensor module, wherein the detector may be a spectrometer module, and wherein the spectrometer module may be a CCD- or CMOS-based spectrometer.

26. (canceled)

27. (canceled)

28. An assembly according to claim 13, characterised in that the means for analysing the emission spectrum comprises any of a spectrometer, a monochromator, a band pass filter or any combination of the above.

29. An assembly according to claim 13, characterised in that more than one wavelength or a range of wavelengths as emitted by plasma is monitored by the means for analysing the emission spectrum.

30. A method of carrying out a vacuum treatment process by means of PVD, CVD or low temperature plasma processing, characterised in that the method includes using an assembly according to claim 1.

31. A method according to claim 30, characterised in that the method includes multiple zone processing using more than one gas analysis apparatus and/or actuator as well as a closed loop process control system with multiple channels.

32. A method according to claim 31, characterised in that a closed loop control system is used to regulate devices to maintain a vacuum treatment process in a desired state, in response to signals generated by the measuring apparatus.
